(19) United States
(12) Patent Application Publication
(10) Pub. No.: US 2025/0350088 A1
(43) Pub. Date: Nov. 13, 2025

(54) VERTICAL CAVITY SURFACE EMITTING LASER DEVICE WITH DUMMY POSTS FOR BONDING

(71) Applicant: Lumentum Operations LLC, San Jose, CA (US)

(72) Inventors: Wei SHI, San Jose, CA (US); Yuefa LI, San Jose, CA (US); Kevin WANG, Fremont, CA (US); Yeyu ZHU, San Jose, CA (US)

(21) Appl. No.: 18/821,763

(22) Filed: Aug. 30, 2024

Related U.S. Application Data
(60) Provisional application No. 63/643,674, filed on May 7, 2024.

(51) Int. Cl. H01S 5/0231; H01S 5/028; H01S 5/183; H01S 5/42

(52) U.S. Cl. CPC H01S 5/0231; H01S 5/028; H01S 5/18305; H01S 5/423

(57) ABSTRACT

In some implementations, a VCSEL device includes a substrate having a first surface and a second surface opposite the first surface. The VCSEL device may include a VCSEL array including a plurality of VCSELs disposed on the first surface of the substrate. The plurality of VCSELs may be configured for backside emission through the substrate. Respective emission areas for the plurality of VCSELs may be defined on the second surface of the substrate. The respective emission areas may define a perimeter of an emission region of the VCSEL device. The VCSEL device may include an anti-reflection (AR) coating on the second surface of the substrate. The VCSEL device may include a plurality of dummy posts disposed on the AR coating. The plurality of dummy posts may be positioned within the emission region, outside of the respective emission areas for the plurality of VCSELs.

### CROSS-REFERENCE TO RELATED APPLICATION

This Patent Application claims priority to U.S. Provisional Patent Application No. 63/643,674, filed on May 7, 2024, and entitled “BACKSIDE EMITTING VERTICAL CAVITY SURFACE EMITTING LASER FOR THERMOCOMPRESSION BONDING.” The disclosure of the prior Application is considered part of and is incorporated by reference into this Patent Application.

### TECHNICAL FIELD

The present disclosure relates generally to lasers and to a vertical cavity surface emitting laser (VCSEL) device with dummy posts for bonding the VCSEL device to other devices, such as for bonding to a VCSEL driver.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, a vertical cavity surface emitting laser (VCSEL) apparatus includes a VCSEL device. The VCSEL device may include a substrate having a first surface and a second surface opposite the first surface. The VCSEL device may include a VCSEL array including a plurality of VCSELs disposed on the first surface of the substrate. The plurality of VCSELs may be configured for backside emission through the substrate. Respective emission areas for the plurality of VCSELs may be defined on the second surface of the substrate. The respective emission areas may define a perimeter of an emission region of the VCSEL device. The VCSEL device may include an anti-reflection (AR) coating on the second surface of the substrate. The VCSEL device may include a plurality of dummy posts extending outwardly from the AR coating. The plurality of dummy posts may be positioned within the emission region, outside of the respective emission areas for the plurality of VCSELs.

In some implementations, a VCSEL device includes a substrate having a first surface and a second surface opposite the first surface. The VCSEL device may include a VCSEL array including a plurality of VCSELs disposed on the first surface of the substrate. The plurality of VCSELs may be configured for backside emission through the substrate. Respective emission areas for the plurality of VCSELs may be defined on the second surface of the substrate. The respective emission areas may define a perimeter of an emission region of the VCSEL device. The VCSEL device may include an AR coating on the second surface of the substrate. The VCSEL device may include a plurality of dummy posts disposed on the AR coating. The plurality of dummy posts may be positioned within the emission region, outside of the respective emission areas for the plurality of VCSELs.

In some implementations, a VCSEL device includes a substrate having a first surface and a second surface opposite the first surface. The VCSEL device may include a VCSEL array including a plurality of VCSELs disposed on the first surface of the substrate. The plurality of VCSELs may be configured for backside emission through the substrate. Respective emission areas for the plurality of VCSELs may be defined on the second surface of the substrate. The respective emission areas may define a perimeter of an emission region of the VCSEL device. The VCSEL device may include an AR coating on the second surface of the substrate. The VCSEL device may include a plurality of dummy posts disposed on the second surface of the substrate and extending through openings in the AR coating. The plurality of dummy posts may be positioned within the emission region, outside of the respective emission areas for the plurality of VCSELs.

### BRIEF DESCRIPTION OF THE DRAWINGS

FIG. 1 shows an example vertical cavity surface emitting laser (VCSEL) on driver (VOD) assembly.

FIG. 2 shows an example VCSEL of a VCSEL device.

FIG. 3A shows a side cross-sectional view of an example VCSEL device.

FIG. 3B shows a bottom view of the example VCSEL device.

FIG. 4 shows examples of positions of dummy posts.

FIG. 5 shows an example of a position of a dummy post.

FIG. 6 shows an example VCSEL apparatus.

FIG. 7 shows an example of the VCSEL apparatus in a bonding process.

### DETAILED DESCRIPTION

The following detailed description of example implementations refers to the accompanying drawings. The same reference numbers in different drawings may identify the same or similar elements.

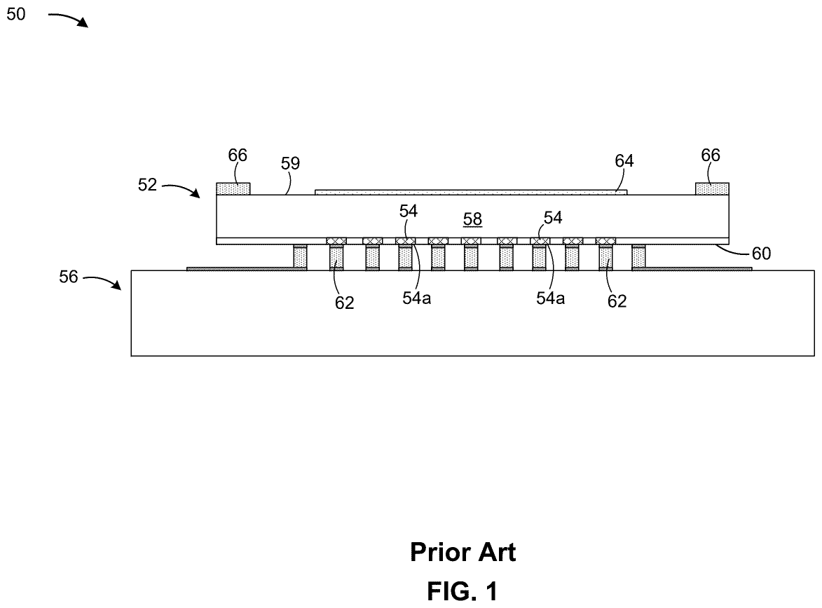

FIG. 1 shows an example vertical cavity surface emitting laser (VCSEL) on driver (VOD) assembly 50. The VOD assembly 50 may include a VCSEL chip 52, with a VCSEL array that includes a plurality of VCSELs 54, mounted directly on a driver chip 56 for the VCSEL chip 52. A VOD configuration may be used in a backside-emitting configuration of the VCSEL chip 52, in which the VCSELs 54 emits light through a backside 59 of a substrate 58 of the VCSEL chip 52. Accordingly, in a VOD configuration, the VCSEL chip 52 may be flip-chip mounted on the driver chip 56, such that the backside 59 of the substrate 58 faces away from the driver chip 56, and a top side 60 of the VCSEL chip 52 faces toward the driver chip 56.

Thermo-compression bonding (TCB) may be used to bond interconnects 62 (e.g., micro bumps or pillars) between the top side 60 of the VCSEL chip 52 and the driver chip 56. For example, the interconnects 62 may be electrically connected to top surfaces 54a of the VCSELs 54. During a bonding operation, the bonding head may be brought into contact with the backside 59 of the substrate 58 of the VCSEL chip 52 to apply heat and pressure through the VCSEL chip 52 into the interconnects 62, thereby bonding the VCSEL chip 52 and the driver chip 56. In some cases, the backside 59 of the substrate 58 may include an anti-reflection (AR) coating 64 that is directly opposite the interconnects 62 used for TCB. Any contact between the AR coating 64 and the bonding head may damage or contaminate the AR coating 64, thereby affecting an optical performance of the VCSEL chip 52 (e.g., in the form of low power or large divergence angle).

Accordingly, the bonding head may be designed to avoid contact with a central region of the VCSEL chip 52 where the AR coating 64 is present. For example, the bonding head may be designed such that it only contacts the VCSEL chip 52 in areas outside of the AR coating 64 (e.g., at frame 66), which may correspond to a perimeter region of the VCSEL chip 52, whereas the interconnects 62 are located under the central region of the VCSEL chip 52 directly opposite the AR coating 64. Thus, the bonding compression force and heat are not applied directly above the interconnects 62, resulting in uneven thermal transfer and/or bonding uniformity, with interconnects 62 at a center of the VCSEL chip 52 (furthest from the contact points of the bonding head) receiving significantly lower force and temperature than interconnects 62 closer to the perimeter region of the VCSEL chip 52. Moreover, because there may be no interconnects 62 in the perimeter region where the bonding head contacts the VCSEL chip 52, the force applied by the bonding head may be uneven across the VCSEL chip 52, resulting in excessive strain on the VCSEL chip 52 and in some cases breaking the VCSEL chip 52. Furthermore, the size of the VCSEL chip 52 and/or the number and arrangement of interconnects 62 beneath the AR coating 64 may be limited to ensure a minimum yield during TCB bonding.

Some implementations described herein relate to a VCSEL device (e.g., a VCSEL chip) that enables a bonding process (e.g., a bonding head during a bonding process) to apply force and heat directly to an emission region of the VCSEL device during a bonding operation (e.g., a VOD bonding operation). In some implementations, the VCSEL device may include a substrate, which has a first surface (e.g., a top surface) and a second surface (e.g., a bottom surface, corresponding to a backside of the VCSEL device) opposite the first surface. A VCSEL array, including a plurality of VCSELs, may be disposed on the first surface of the substrate. The VCSELs may be configured for backside emission through the substrate, and thus, respective emission areas for the VCSELs may be defined on the second surface of the substrate. An AR coating may be disposed on the second surface of the substrate (e.g., corresponding to a backside of the VCSEL device), covering the emission areas of the VCSELs. An area containing the emission areas of the VCSELs may be referred to herein as an “emission region” of the VCSEL device.

The VCSEL device may include one or more dummy posts extending outwardly from the AR coating. In particular, the dummy posts project further from the second surface of the substrate than the AR coating. In this way, the dummy posts, and not the AR coating, are points of contact for the bonding head during a bonding operation of the VCSEL device (e.g., during bonding of a driver device to the VCSEL device). The dummy posts may be of a height that prevents contact with the AR coating during a bonding operation of the VCSEL device. In other words, when a bonding head is brought into contact with the VCSEL device, the contact and pressure of the bonding head is experienced by and distributed through the dummy posts, thereby protecting the AR coating from damage and more uniformly distributing the pressure and heat across the VCSEL device. Accordingly, during a bonding operation to bond the VCSEL device to a driver device via interconnects that are opposite the emission region of the VCSEL device, the dummy posts allow the bonding head to be centered over the interconnects without harm to the AR coating, allowing thermal and force transference through the dummy posts, thereby uniformly bonding the interconnects and reducing stress on the VCSEL device during bonding.

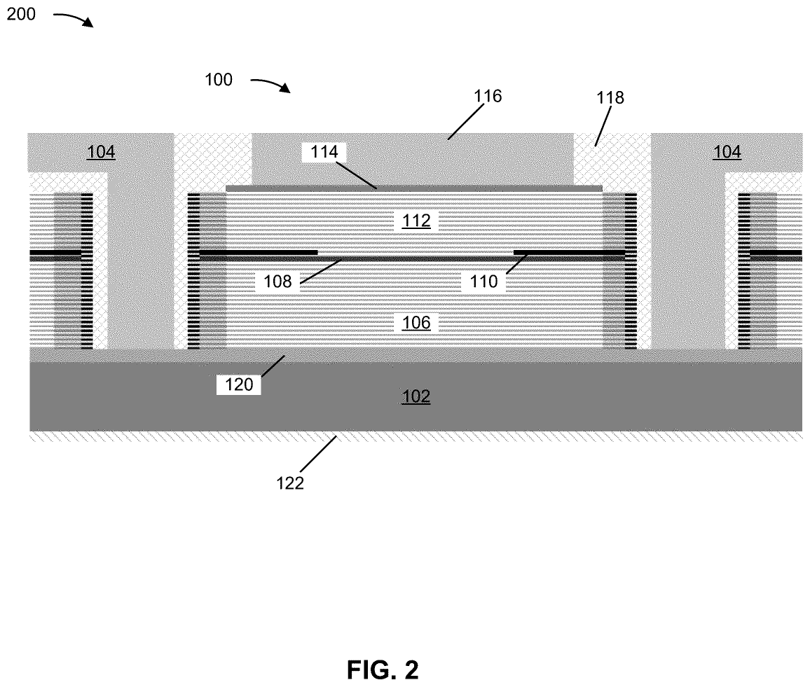

FIG. 2 shows an example VCSEL 100 of a VCSEL device 200 (e.g., a VCSEL chip). In some implementations, the VCSEL 100 may be included in an array of VCSELs 100 of the VCSEL device 200, as described herein. In some implementations, as illustrated in FIG. 1, the VCSEL 100 is a backside-emitting (also referred to as “back emitting” or “bottom emitting”) emitter. As shown in FIG. 2, the VCSEL device 200 may include a substrate 102 that supports the VCSEL 100 (e.g., supports an array of VCSELs 100). The VCSEL 100 may include a bottom mirror structure 106, a cavity including one or more active regions (herein referred to as cavity region 108), a confinement layer 110 that forms a confinement aperture, and/or a top mirror structure 112. A contact layer 114 may be disposed on the top mirror structure 112 and a metal layer 116 (e.g., serving as an anode) may be electrically connected to the contact layer 114. A metal layer 104 (e.g., serving as a cathode) may be electrically connected to the bottom mirror structure 106 via a contact layer 120. A dielectric layer 118 may provide isolation between the metal layer 104 and the metal layer 116. In some implementations, an AR coating 122 may be disposed along the substrate 102 opposite the VCSEL 100. The AR coating 122 may include silicon nitride (SiN).

The substrate 102 includes a supporting material upon which, or within which, one or more layers or features of the VCSEL 100 are grown or fabricated. In some implementations, the substrate 102 includes an n-type material. In some implementations, the substrate 102 includes a semi-insulating type of material. In some implementations, the semi-insulating type of material may be used in order to reduce optical absorption from the substrate 102. In some implementations, the substrate 102 may be formed from a semiconductor material, such as gallium arsenide (GaAs), indium phosphide (InP), or another type of semiconductor material.

The bottom mirror structure 106 is a bottom reflector of an optical resonator of the VCSEL 100. For example, the bottom mirror structure 106 may include a distributed Bragg reflector (DBR), a dielectric mirror, or another type of mirror structure. In some implementations, the bottom mirror structure 106 is formed from an n-type material. In some implementations, the bottom mirror structure 106 is on a top surface of the substrate 102. In some implementations, the bottom mirror structure 106 includes a set of layers (e.g., aluminum gallium arsenide (AlGaAs) layers) grown using a metal-organic chemical vapor deposition (MOCVD) technique, a molecular beam epitaxy (MBE) technique, or another technique.

The cavity region 108 includes one or more layers where electrons and holes recombine to emit light and define the emission wavelength range of the VCSEL 100. For example, the cavity region 108 may include one or more active regions in the form of one or more quantum wells (QWs). An optical thickness of the cavity region 108 (including the one or more active regions and any cavity spacer layers), the top mirror structure 112, and the bottom mirror structure 106 defines the resonant cavity wavelength of the VCSEL 100, which may be designed within an emission wavelength range of the cavity region 108 to enable lasing. In some implementations, the cavity region 108 may be formed on the bottom mirror structure 106. In some implementations, the cavity region 108 includes a set of layers grown using an MOCVD technique, an MBE technique, or another technique.

The confinement layer 110 is a layer that provides optical and/or electrical confinement for the VCSEL 100. In some implementations, the confinement layer 110 enhances carrier and mode confinement of the VCSEL 100 and, therefore, can improve performance of the VCSEL 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, the confinement layer 110 is on a side of the cavity region 108 nearer to the bottom mirror structure 106 (i.e., on a substrate side of the cavity region 108). In some implementations, the confinement layer 110 is on a side of the cavity region 108 nearer to the top mirror structure 112 (i.e., on a non-substrate side of the cavity region 108).

In some implementations, the confinement layer 110 is an oxide layer formed as a result of oxidation of one or more epitaxial layers of the VCSEL 100. For example, the confinement layer 110 may be an aluminum oxide (Al₂O₃) layer formed as a result of oxidation of an epitaxial layer (e.g., an AlGaAs layer, an AlAs layer, or the like). In some implementations, oxidation trenches (shown as filled in FIG. 1) etched around the VCSEL 100 may allow steam to access the epitaxial layer(s) from which the confinement layer 110 is formed. In some implementations, the oxidation trenches may not fully enclose the confinement layer 110. For example, the oxidation trenches may follow the general shape of the confinement region, but there may be gaps between adjacent oxidation trenches. In some implementations, the confinement layer 110 may follow the general geometric shape, but may have variations associated with shapes or locations of the oxidation trenches and/or variations associated with an oxidation rate. In some implementations, in addition to the confinement layer 110, the VCSEL 100 may include one or more other types of structures or layers that provide current confinement, such as an implant passivation structure, a mesa isolation structure, a moat trench isolation structure, a buried tunnel junction, or the like. Additionally, or alternatively, such other types of structures or layers for providing current confinement may be included in or integrated with the confinement layer 110. In some implementations, the confinement layer 110 defines a confinement aperture.

The top mirror structure 112 is a top reflector of the optical resonator of the VCSEL 100. For example, the top mirror structure 112 may include a DBR, a dielectric mirror, or the like. In some implementations, the top mirror structure 112 is formed from a p-type material. In some implementations, the top mirror structure 112 includes a set of layers (e.g., AlGaAs layers) grown using an MOCVD technique, an MBE technique, or another technique. In some implementations, the top mirror structure 112 is grown on or over the cavity region 108.

The dielectric layer 118 is a layer that at least partially insulates the metal layer 104 from the metal layer 116. In some implementations, the dielectric layer 118 may include, for example, SiN, silicon dioxide (SiO₂), a polymer dielectric, or another type of insulating material.

The number, arrangement, thicknesses, order, symmetry, or the like, of layers shown in FIG. 2 are provided as an example. In practice, the VCSEL 100 and/or the VCSEL device 200 may include additional layers, fewer layers, different layers, differently constructed layers, or differently arranged layers than those shown in FIG. 2. For example, in some implementations, the location of anode and cathode contacts may be different or reversed from that shown in FIG. 2. Additionally, or alternatively, a set of layers (e.g., one or more layers) of the VCSEL 100 and/or the VCSEL device 200 may perform one or more functions described as being performed by another set of layers of the VCSEL 100 and/or the VCSEL device 200, and any layer may include more than one layer. Other configurations of layers and structures to form a VCSEL 100 are possible, this one is provided merely as an example. For example, MESA structured VCSELs, multi-junction VCSELs and any other structure of a backside emitting VCSEL or VCSEL array may be provided by VCSEL 100.

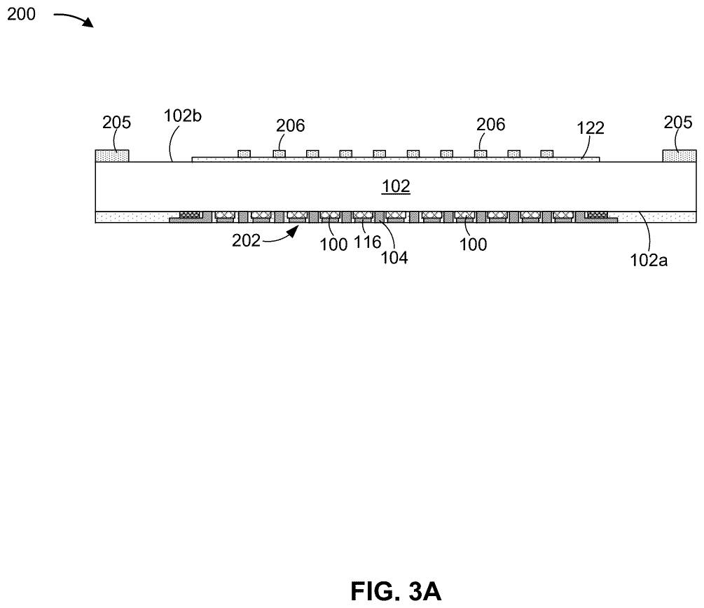

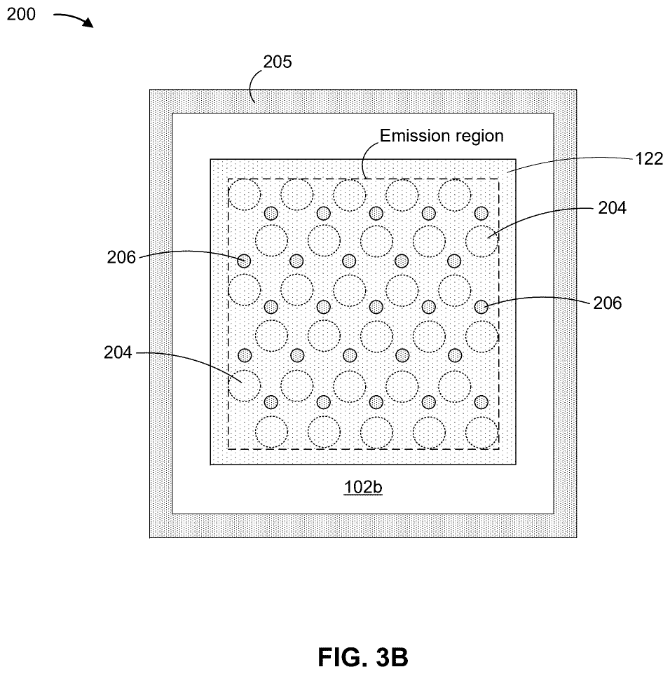

FIG. 3A shows a side cross-sectional view of an example VCSEL device 200, and FIG. 3B shows a bottom view of the example VCSEL device 200. The VCSEL device 200 may be a VCSEL chip. The VCSEL device 200 may include the substrate 102, which has a first surface 102a (e.g., a top surface) and a second surface 102b (e.g., a bottom surface, corresponding to a backside of the VCSEL device 200) opposite the first surface 102a, and a VCSEL array 202 disposed on the first surface 102a of the substrate 102 (e.g., the substrate 102 is a common substrate for the VCSEL array 202). For example, a set of epitaxial layers, in which the VCSEL array 202 is defined, may be disposed on the first surface 102a of the substrate 102. The VCSEL array 202 may include a plurality of VCSELs 100, each of which may have a structure as described in FIG. 2 or any other back-emitting VCSEL structure. In some implementations, the VCSELs 100 of the VCSEL array 202 may have a fine emitter pitch, such as a pitch of less than 45 micrometers (μm).

The VCSELs 100 are configured for backside emission through the substrate 102 (e.g., through the second surface 102b, or backside, of the substrate 102). Thus, respective emission areas 204 for the VCSELs 100 may be defined on the second surface 102b of the substrate 102. For example, an emission area 204 may correspond to a beam diameter that would result at the second surface 102b of the substrate 102 from a beam emitted by a VCSEL 100 (e.g., as the beam propagates through the substrate 102 and diverges). As shown in FIG. 3B, the emission areas 204 may define a perimeter of an emission region of the VCSEL device 200. For example, the emission region may be a minimum region (e.g., bounding box) of the second surface 102b of the substrate 102 that encompasses all of the emission areas 204. A region of the second surface 102b of the substrate 102, coinciding with the AR coating 122, may encompass the emission region of the VCSEL device 200. For example, each of the emission areas 204 may be covered by the AR coating 122.

A frame 205 is also disposed on the second surface 102b of the substrate 102 (e.g., a backside of the VCSEL device 200), and may surround or partially surround the emission region of the VCSEL device 200. The frame 205 may be composed of a metal or a non-metallic material. The frame 205 may provide a point of contact for the bonding head during a bonding operation of the VCSEL device 200. Accordingly, the frame 205 may project further from the second surface 102b of the substrate 102 than the AR coating 122.

The VCSEL device 200 may include one or more dummy posts 206 (e.g., a plurality of dummy posts 206) extending outwardly from the AR coating 122. In particular, the dummy posts 206 may project further from the second surface 102b of the substrate 102 than the AR coating 122. For example, the dummy posts 206 may extend from 1 to 2 μm or from 2 to 3 μm beyond the surface of the AR coating 122. In this way, the dummy posts 206, and not the AR coating 122, are to be points of contact for a bonding head during a bonding operation of the VCSEL device 200 and the dummy posts prevent contact with the AR coating 122 during a bonding operation or otherwise. In other words, when the bonding head is brought into contact with the VCSEL device 200, the contact and pressure of the bonding head is experienced by and distributed into the dummy posts 206, thereby protecting the AR coating 122 from damage. Accordingly, the dummy posts 206 allow the bonding head to provide pressure in the emission region of the VCSEL device 200. For example, the dummy posts 206 allow the bonding head to be centered over interconnects being bonded to the VCSEL device 200 without harm to the AR coating 122, allowing thermal and force transference through the dummy posts 206, thereby uniformly bonding the interconnects and reducing stress on the VCSEL device 200 during bonding.

The dummy posts 206 may be rod-shaped, spherical, box-shaped, or another suitable shape that would prevent contact between the bonding head and the AR coating 122 during a bonding operation. A top surface of the dummy posts 206 may be flat to receive the bonding head for improved pressure and thermal transfer during a bonding process. The dummy posts 206 may be composed of one or more metals, such as aluminum, gold, titanium, chromium, nickel, platinum, copper, palladium, silver, and/or tungsten, among other examples.

In some implementations, the dummy posts 206 may be disposed on the AR coating 122. In some implementations, the dummy posts 206 may be patterned on the AR coating 122. For example, the dummy posts 206 may be formed on the AR coating 122 using a metal liftoff technique, an electron beam (E-beam) evaporation technique, or a sputtering deposition technique, thereby facilitating tight control of the dimensions of the dummy posts 206 with high uniformity. Disposing the dummy posts 206 on the AR coating 122 may be advantageous to avoid any irregularities when forming the AR coating 122 and to incorporate the formation of the dummy posts 206 into pre-existing metal deposition steps in the manufacturing process. In some implementations, the dummy posts 206 may be disposed directly on the second surface 102b of the substrate 102, extending through openings in the AR coating 122. For example, following deposition of the AR coating 122, the AR coating 122 may be removed (e.g., by etching) at the locations for the dummy posts 206, and the dummy posts 206 may be formed at those locations directly on the substrate 102.

The dummy posts 206 may be positioned within the emission region defined by the emission areas 204 of the VCSELs 100. In some implementations, one or more dummy posts 206 may be positioned outside of the emission region (e.g., but within an area of the AR coating 122). The dummy posts 206 positioned outside of the emission region may have corresponding heights and/or widths (e.g., diameters) to the dummy posts 206 positioned within the emission region. In some implementations, the dummy posts 206 positioned outside of the emission region may have greater widths (e.g., diameters) than the dummy posts 206 positioned within the emission region.

Moreover, the dummy posts 206 may be positioned outside of the emission areas 204 of the VCSELs 100. For example, the dummy posts 206 may be positioned between emission areas 204, but without overlapping any of the emission areas 204. Accordingly, a width (e.g., a diameter) of each dummy post 206 may be constrained by sizes of the emission areas 204 (e.g., in order to avoid overlapping with the emission areas 204). In some implementations, the width (e.g., the diameter) of each dummy post 206 may be from 2 to 20 μm, such as from 5 to 15 μm.

A height of each dummy post 206 (e.g., an amount by which each dummy post 206 projects relative to the second surface 102b of the substrate 102) may be constrained by a minimum distance between the dummy post 206 and the emission areas 204, and the divergence angle of the light to exit from the emission areas 204. For example, based on the minimum distance between the dummy post 206 and the emission areas 204, the height of the dummy post 206 should be low enough such that light to exit from the emission areas (e.g., at the divergence angle) clears the dummy post 206 (e.g., the light is not blocked by the dummy post 206). In some implementations, the height of each dummy post 206 may be no more than, or may correspond to (e.g., may be the same as, or substantially the same as, such as within ±1%), a height of the frame 205 (e.g., the dummy posts 206 may project the same amount as the frame 205 relative to the second surface 102b of the substrate 102), which facilitates formation of the frame 205 and dummy posts 206 as part of the same manufacturing step (in which case the frame 205 may have the same composition as the composition of the dummy posts 206). In some implementations, the height of each dummy post 206 may be greater than a height of the frame 205 (e.g., the dummy posts 206 may project further relative to the second surface 102b of the substrate 102 than the frame 205), which may allow more heat and pressure transfer through the dummy posts 206. In some implementations, the height of each dummy post 206 may be greater than a maximum surface roughness variation of the bonding head to be used for bonding the VCSEL device 200.

As indicated above, FIGS. 3A-3B are provided as an example. Other examples may differ from what is described with regard to FIGS. 3A-3B.

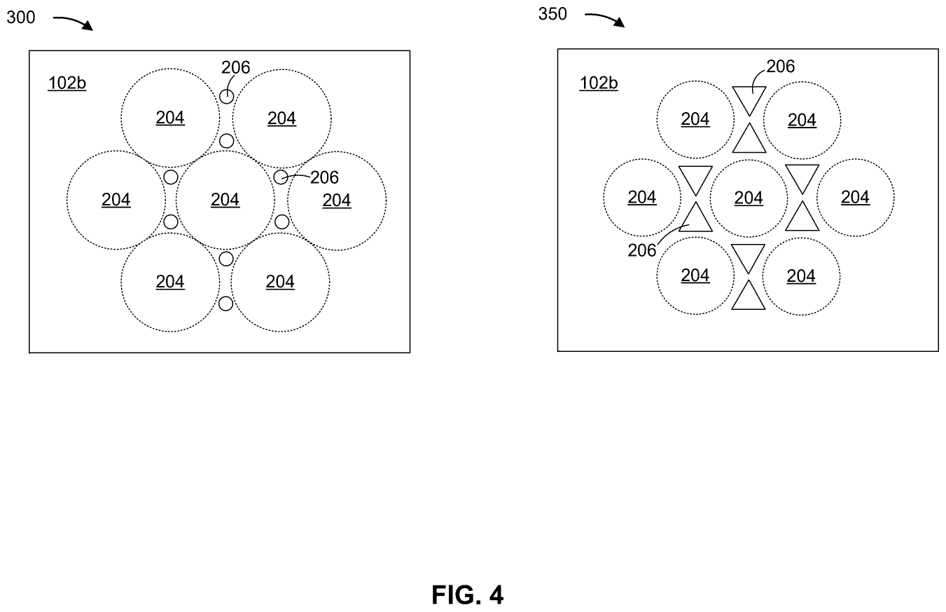

FIG. 4 shows examples 300 and 350 of positions of dummy posts 206. In examples 300 and 350 a top view of the second surface 102b of the substrate 102 (e.g., a backside of the VCSEL device 200) is shown. As shown in examples 300 and 350, widths (e.g., diameters) of the dummy posts 206 may increase as the diameters of the emission areas 204 decrease. The diameters of the emission areas 204 may be manipulated by changing optical aperture diameter in a VCSEL 100 and/or by changing the thickness of the substrate 102. Different shapes of emission areas 204 are equally possible depending on the individual VCSELs 100.

In example 300, the emission areas 204 are relatively large (e.g., having a circular shape with diameter of about 35 micrometers (μm)), such that each emission area 204 is abutting at least one other emission area 204. Thus, the dummy posts 206 may be relatively small (e.g., having a circular shape and a diameter of about 5 μm). As shown in example 300, one or more dummy posts 206 may be completely bounded by multiple emission areas 204. In example 300, the dummy posts 206 have a circular shape; however, other shapes may be used for the dummy posts 206. In example 350, the emission areas 204 are relatively small (e.g., having a diameter of about 33 μm). Thus, the dummy posts 206 may be relatively large (e.g., having a width of about 14 μm). In example 350, the dummy posts 206 have a triangular shape; however, other shapes may be used for the dummy posts 206.

As indicated above, FIG. 4 is provided as an example. Other examples may differ from what is described with regard to FIG. 4.

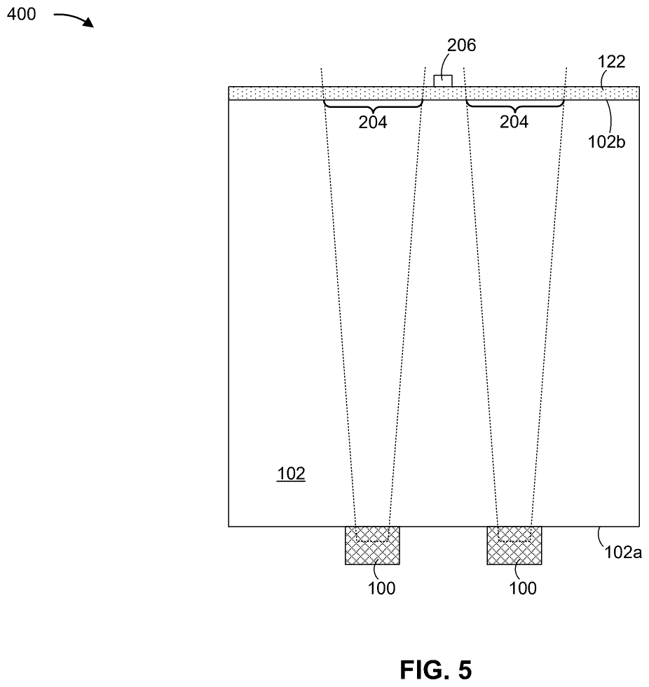

FIG. 5 shows an example 400 of a position of a dummy post 206. As shown, light emitted by the VCSELs 100, represented in dashed lines, may diverge as the light propagates through the substrate 102, thereby defining emission areas 204 on the second surface 102b of the substrate 102. As further shown, the dummy post 206, extending outwardly from the AR coating 122, is positioned outside of the emission areas 204. Moreover, a height of the dummy post 206 may be constrained such that the dummy post 206 does not intersect with the light exiting out from the substrate 102. While the dummy posts 206 are illustrated as having vertical sides, the sides may be differently shaped so long as they do not intersect with the path of light from the VCSELs 100.

As indicated above, FIG. 5 is provided as an example. Other examples may differ from what is described with regard to FIG. 5.

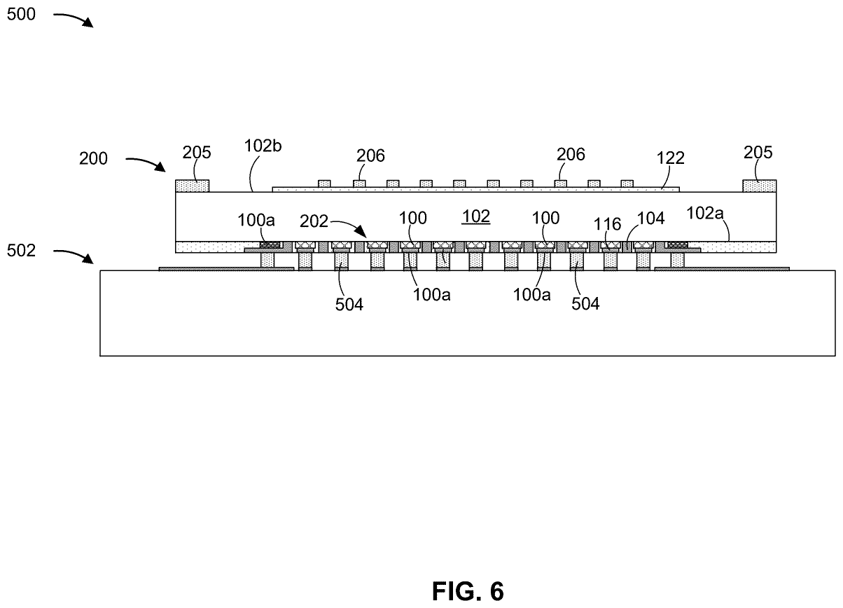

FIG. 6 shows an example VCSEL apparatus 500. The VCSEL apparatus 500 includes the VCSEL device 200 and a driver device 502 (e.g., a silicon driver, such as a complementary metal oxide semiconductor (CMOS) driver) for the VCSEL device 200. For example, the driver device 502 may be a driver chip. In some implementations, the VCSEL apparatus 500 may be incorporated into a time of flight (ToF) camera, a light detection and ranging (lidar) system, a three-dimensional sensing system, or any other system.

As shown, in the VCSEL apparatus 500, the VCSEL device 200 may be stacked on the driver device 502 in a VOD configuration (e.g., using direct chip attachment). The driver device 502 may be configured to cause electrical current to flow to the VCSELs 100 of the VCSEL device 200. For example, the driver device 502 may be configured to address (e.g., activate) individual VCSELs 100 or to address subarrays of the VCSELs 100.

The driver device 502 (e.g., a redistribution layer of the driver device 502) may be electrically connected to the VCSEL device 200 by a plurality of interconnects 504 (e.g., copper pillars, gold bumps, micro bumps, or the like). For example, each VCSEL 100 may be electrically connected to a respective interconnect 504 (e.g., the interconnects 504 electrically connect individual VCSELs 100 to the driver device 502 to provide individual addressability of the VCSELs 100), or the VCSELs 100 may be grouped into multiple subarrays of VCSELs 100, and each subarray may be electrically connected to a respective interconnect 504. The interconnects 504 may be electrically connected to the metal layer 116 and the metal layer 104 of the VCSELs 100. For example, a metal layer 116 may be disposed on each VCSEL 100 to serve as a respective anode contact for each VCSEL 100, and the metal layer 104 may serve as a shared cathode contact for the VCSELs 100. For example, the metal layer 104 may extend across one or more dummy emitters 100a, positioned at an outer edge of the VCSEL array 202, for cathode connectivity to one or more interconnects 504. A dummy emitter 100a may have an epitaxial structure similar to a VCSEL 100, but may lack metal connections similar to a VCSEL 100, such that current flows across the top of the dummy emitter 100a rather than flowing through the dummy emitter 100a. In some implementations, the VCSELs 100 may be configured with a shared anode contact and respective cathode contacts. In some implementations, the VCSELs 100 may be configured with respective anode contacts and respective cathode contacts.

In some implementations, the interconnects 504 may be connected to the VCSEL device 200 at top surfaces 100a of the VCSELs 100 (e.g., the surfaces of the VCSELs 100 facing the driver device 502). Thus, the interconnects 504 and the dummy posts 206 may be connected to the VCSEL device 200 at opposite sides of the VCSEL device 200. The dummy posts 206 may be approximately vertically aligned with the electrical connections of the VCSELs 100 made via the metal layer 116 and the metal layer 104. For example, the electrical connections of the metal layer 116 and the metal layer 104 to the VCSELs 100 may be proximate to the emission areas 204 of the VCSELs 100 (described in connection with FIGS. 3B, 4, and 5). Accordingly, the dummy posts 206 may be positioned between the emission areas 204 to improve the application of pressure and heat to the electrical connections of the metal layer 116 and the metal layer 104.

As indicated above, FIG. 6 is provided as an example. Other examples may differ from what is described with regard to FIG. 6.

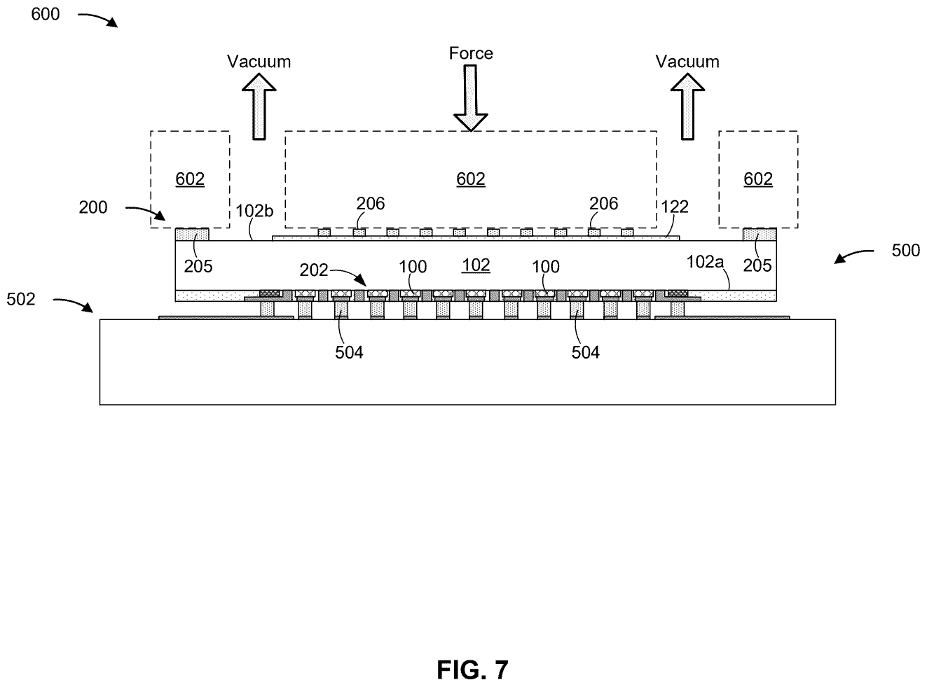

FIG. 7 shows an example 600 of the VCSEL apparatus 500 in a bonding process. A bonding head 602 may be used for a bonding operation for the VCSEL apparatus 500. For example, the bonding operation may be for thermo-compression bonding of the VCSEL device 200 to the driver device 502. During the bonding operation, the bonding head 602 may apply heat and pressure through the VCSEL device 200 into the interconnects 504, thereby forming a bond between the VCSEL device 200 and the driver device 502 via the interconnects 504. In some implementations, a vacuum may be applied by or through the bonding head 602 in order to retain the VCSEL device 200 on the bonding head 602.

As shown, the bonding head 602 may apply heat and downward force on the frame 205. As described herein, this heat and force applied at the edge of the VCSEL device 200 is not centered over the interconnects 504 where the bonding occurs, and may place stress on the VCSEL device 200. As further shown, the bonding head 602 may also apply heat and downward force on the dummy posts 206. The dummy posts 206 allow the bonding head 602 to be applied directly over (e.g. centered over) the interconnects 504 without harm to the AR coating 122, allowing thermal and force transference through the dummy posts 206, thereby improving (e.g. more uniformly) bonding of the interconnects 504 and reducing stress on the VCSEL device 200 during bonding. For example, without the dummy posts 206, the bonding head 602 could not be centered over the interconnects 504 because any contact with the AR coating 122 would damage the AR coating 122.

As indicated above, FIG. 7 is provided as an example. Other examples may differ from what is described with regard to FIG. 7.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “top,” “bottom,” “back,” “front,” “above,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL) apparatus, comprising:
a VCSEL device, comprising:
a substrate having a first surface and a second surface opposite the first surface;
a VCSEL array comprising a plurality of VCSELs disposed on the first surface of the substrate,
wherein the plurality of VCSELs are configured for backside emission through the substrate,
wherein respective emission areas for the plurality of VCSELs are defined on the second surface of the substrate, and
wherein the respective emission areas define a perimeter of an emission region of the VCSEL device;
an anti-reflection (AR) coating on the second surface of the substrate; and
a plurality of dummy posts extending outwardly from the AR coating,
wherein the plurality of dummy posts are positioned within the emission region, outside of the respective emission areas for the plurality of VCSELs.

2. The VCSEL apparatus of claim 1, wherein heights of the plurality of dummy posts are constrained by:
a minimum distance between the plurality of dummy posts and the respective emission areas, and
a divergence angle of light to exit from the respective emission areas.

3. The VCSEL apparatus of claim 1, wherein the plurality of dummy posts are points of contact during a bonding operation for the VCSEL apparatus, and the plurality of dummy posts prevent the AR coating from being a point of contact during the bonding operation.

4. The VCSEL apparatus of claim 1, wherein the plurality of dummy posts are disposed on the AR coating.

5. The VCSEL apparatus of claim 1, wherein the plurality of dummy posts are disposed on the second surface of the substrate and extend through openings in the AR coating.

6. The VCSEL apparatus of claim 1, further comprising a frame disposed on the second surface of the substrate and surrounding the emission region.

7. The VCSEL apparatus of claim 6, wherein heights of the plurality of dummy posts correspond to a height of the frame.

8. The VCSEL apparatus of claim 1, wherein a dummy post, of the plurality of dummy posts, is completely bounded by multiple emission areas of the respective emission areas.

9. The VCSEL apparatus of claim 1, further comprising a dummy post, extending outwardly from the AR coating, positioned outside of the emission region,
wherein heights of the plurality of dummy posts correspond to a height of the dummy post.

10. The VCSEL apparatus of claim 1, further comprising a driver device stacked on the VCSEL device in a VCSEL on driver configuration,
wherein a plurality of interconnects electrically connect the plurality of VCSELs to the driver device.

11. A vertical cavity surface emitting laser (VCSEL) device, comprising:
a substrate having a first surface and a second surface opposite the first surface;
a VCSEL array comprising a plurality of VCSELs disposed on the first surface of the substrate,
wherein the plurality of VCSELs are configured for backside emission through the substrate,
wherein respective emission areas for the plurality of VCSELs are defined on the second surface of the substrate, and
wherein the respective emission areas define a perimeter of an emission region of the VCSEL device;
an anti-reflection (AR) coating on the second surface of the substrate; and
a plurality of dummy posts disposed on the AR coating,
wherein the plurality of dummy posts are positioned within the emission region, outside of the respective emission areas for the plurality of VCSELs.

12. The VCSEL device of claim 11, wherein heights of the plurality of dummy posts are constrained by:
a minimum distance between the plurality of dummy posts and the respective emission areas, and
a divergence angle of light to exit from the respective emission areas.

13. The VCSEL device of claim 11, further comprising a frame disposed on the second surface of the substrate and surrounding the emission region.

14. The VCSEL device of claim 11, wherein the VCSEL device is stacked on a driver device in a VCSEL on driver configuration, and
wherein a plurality of interconnects electrically connect individual VCSELs of the plurality of VCSELs to the driver device.

15. The VCSEL device of claim 11, wherein a dummy post, of the plurality of dummy posts, is completely bounded by multiple emission areas of the respective emission areas.

16. A vertical cavity surface emitting laser (VCSEL) device, comprising:
a substrate having a first surface and a second surface opposite the first surface;
a VCSEL array comprising a plurality of VCSELs disposed on the first surface of the substrate,
wherein the plurality of VCSELs are configured for backside emission through the substrate,
wherein respective emission areas for the plurality of VCSELs are defined on the second surface of the substrate, and
wherein the respective emission areas define a perimeter of an emission region of the VCSEL device;
an anti-reflection (AR) coating on the second surface of the substrate; and
a plurality of dummy posts disposed on the second surface of the substrate and extending through openings in the AR coating,
wherein the plurality of dummy posts are positioned within the emission region, outside of the respective emission areas for the plurality of VCSELs.

17. The VCSEL device of claim 16, wherein heights of the plurality of dummy posts are constrained by:
a minimum distance between the plurality of dummy posts and the respective emission areas, and
a divergence angle of light to exit from the respective emission areas.

18. The VCSEL device of claim 16, further comprising a frame disposed on the second surface of the substrate and surrounding the emission region.

19. The VCSEL device of claim 18, wherein heights of the plurality of dummy posts correspond to a height of the frame.

20. The VCSEL device of claim 16, wherein the VCSEL device is stacked on a driver device in a VCSEL on driver configuration, and
wherein a plurality of interconnects electrically connect the plurality of VCSELs to the driver device.
